(19) United States
(12) Patent Application Publication
(10) Pub. No.: US 2007/0223735 A1
(43) Pub. Date: Sep. 27, 2007

(54) Electroacoustic Transducer System and Manufacturing Method Thereof

(75) Inventors: Janice L. LoPresti, Itasca, IL (US); Vignesh Jayanth, Chicago, IL (US); Gwendolyn P. Massingill, Aurora, IL (US)

Correspondence Address: MARSHALL, GERSTEIN & BORUN LLP, 233 S. WACKER DRIVE, SUITE 6300, SEARS TOWER, CHICAGO, IL, 60606, US

(73) Assignee: KNOWLES ELECTRONICS, LLC, Itasca, IL (US)

(21) Appl. No.: 11/691,947

(22) Filed: Mar. 27, 2007

Related U.S. Application Data
(60) Provisional application No. 60/743,805, filed on Mar. 27, 2006.

(51) Int. Cl. H03G 5/00

(52) U.S. Cl. 381/99

(57) ABSTRACT

A transducer system may include multiple transducers. The transducers may be mounted together and may include either the same transducer type or different transducer types, depending on the desired applications. The transducers may be receivers which are aligned and joined. A coupling circuit may be provided and coupled to one or both of the transducers.

### CROSS-REFERENCE TO RELATED APPLICATION

This patent claims benefit under 35 U.S.C. § 119(e) to U.S. Provisional Application Ser. No. 60/743,805, filed Mar. 27, 2006 and entitled Electroacoustic Transducer System and Manufacturing Thereof, the disclosure of which is hereby expressly incorporated herein for all purposes

### BRIEF DESCRIPTION OF THE DRAWINGS

For a more complete understanding of the disclosure, reference should be made to the following detailed description and accompanying drawings wherein:

FIG. 1 is a block diagram of an electroacoustic transducer system according to various embodiments of the present invention;

FIG. 2 is a block diagram of an electroacoustic transducer system, in accordance with various embodiments of the present invention;

FIG. 3 is a cross-sectional view of a transducer for an electroacoustic transducer system, in accordance with various embodiments of the present invention;

FIG. 4 is a cross-sectional view of a dual transducer device for an electroacoustic transducer system, in accordance with various embodiments of the present invention;

FIG. 5 is a side elevational view of a dual transducer device disposed in a capsule for an electroacoustic transducer system in accordance with various embodiments of the present invention;

FIG. 6 is a block diagram of another exemplary electroacoustic transducer system in accordance with various embodiments of the present invention;

FIG. 7 is a block diagram of another exemplary electroacoustic transducer system in accordance with various embodiments of the present invention;

FIG. 8 is a block diagram of another exemplary electroacoustic transducer system in accordance with various embodiments of the present invention;

FIG. 9 is a block diagram of another exemplary electroacoustic transducer system system in accordance with various embodiments of the present invention;

FIG. 10 is a block diagram of another exemplary electroacoustic transducer system in accordance with various embodiments of the present invention;

FIG. 11 is a block diagram of another exemplary electroacoustic transducer system in accordance with various embodiments of the present invention; and

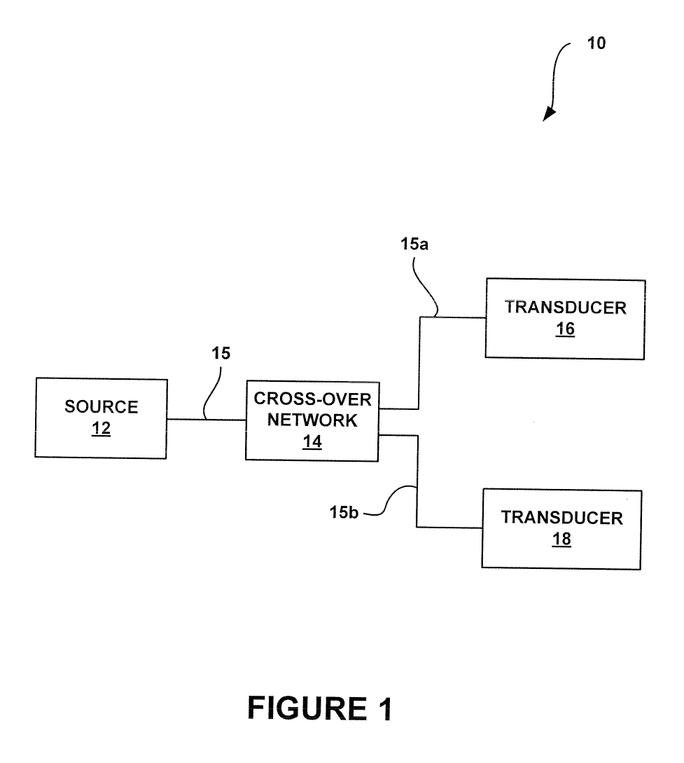

FIGS. 1-13 are graphs used in explanation of the operation of the electroacoustic transducer system according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

While the present disclosure is susceptible to various modifications and alternative forms, certain embodiments are shown by wavy of example in the drawings and these embodiments will be described in detail herein. It will be understood, however, that this disclosure is not intended to limit the invention to the particular forms described, but to the contrary, the invention is intended to cover all modifications, alternatives, and equivalents falling within the spirit and scope of the invention defined by the appended claims.

FIG. 1 illustrates a block diagram of an electroacoustic transducer system 10 in accordance with one or more of the herein described embodiments. The system 10 can be employed in various types of electronic devices such as computers (e.g. desktops, laptops, notebooks, tablets, hand-held computers, Personal Digital Assistants (PDAs), etc), communication devices (e.g. cellular phones, web-enabled cellular telephones, cordless phones, pagers, etc), computer-related peripherals (e.g. printers, scanners, monitors, etc), entertainment devices (e.g. televisions, radios, stereos, tape and compact disc players, digital cameras, cameras, video cassette recorders, MP3 (Motion Picture Expert Group, Audio Layer 3) players, etc), listening devices (e.g. hearing aids, earphones, headphones, Bluetooth wireless headsets, insert earphone, etc) and the like. Other examples of devices are possible. In many of these embodiments, the system 10 comprises a signal source 12, a cross-over network 14, and a plurality of transducers 16, 18. An audio signal 15, including variously processed signals, from the signal source 12 is presented to an input of the cross-over network 14. The signal source 12 may be any conventional device for the generation of the electrical signal depending on the desired applications. Other audio components may be substituted without varying from the scope of the invention. The cross-over network 14 divides the signal 15 according to frequency, supplying a selected range or band of signals over line 15a to drive the transducer 16, and the remaining frequency band over line 15b to drive the transducer 18. The cross-over network 14 may be a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof. Other types of electrical filters are possible and may be used separately or in combination. It will be understood that one or more cross-over networks may be included. More details about the cross-over network will follow.

The transducers 16, 18 receive selected frequency ranges or bands of the signals 15a, 15b from the cross-over network 14 and convert the selected ranges or bands to acoustic energy. The transducers 16, 18 may be receivers, speakers, MEMS receivers, or combinations thereof for the conversation of an electrical audio frequency signal to an acoustic signal, depending on the desired applications. Alternatively, the transducers 16, 18 may be a conjoined microphone and receiver assembly disclosed in U.S. patent application Ser. No. 11/382,318, the disclosure of which is herein incorporated by reference in its entirely for all purpose. In the embodiment, the transducers 16, 18 may be low-range frequency (LF) receivers also known as woofers, mid-range frequency (MF) receivers, high-range frequency (HF) receivers also known as tweeters, or combination thereof.

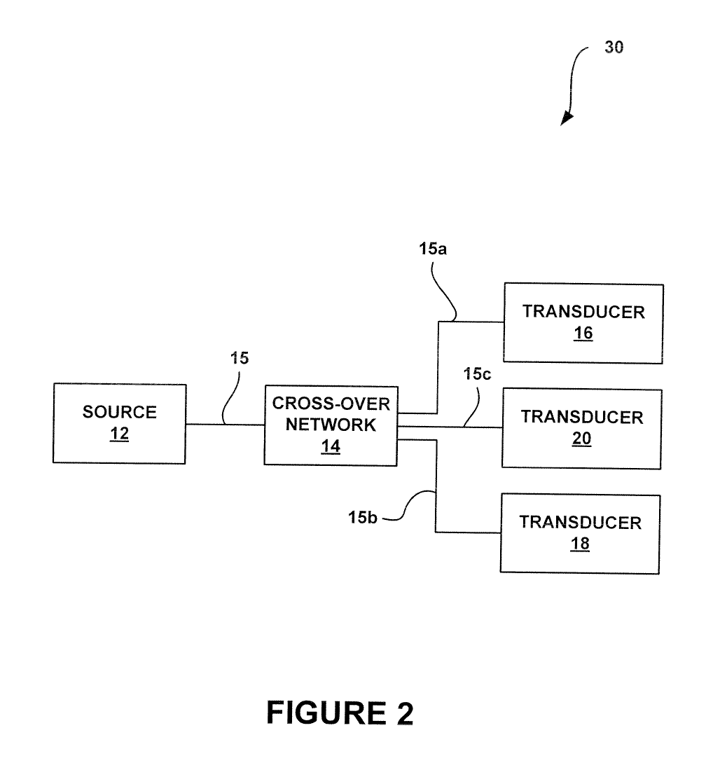

FIG. 2 illustrates a block diagram of an electroacoustic transducer system 30, in accordance with an alternate embodiment of the present invention. The system 30 comprises an additional transducer 20 electrically coupled to an output of a cross-over network 14. Like FIG. 1, a selected range or band of signals over line 15c is supplied by the cross-over network 14 to drive the transducer 20. The transducer 20 then converts the selected range or band to acoustic energy. The transducer 20 may be a woofer, a MF receiver, or a tweeter. It will be understood that three or more transducers may be included without varying from the scope of the invention. More details about the transducers will follow.

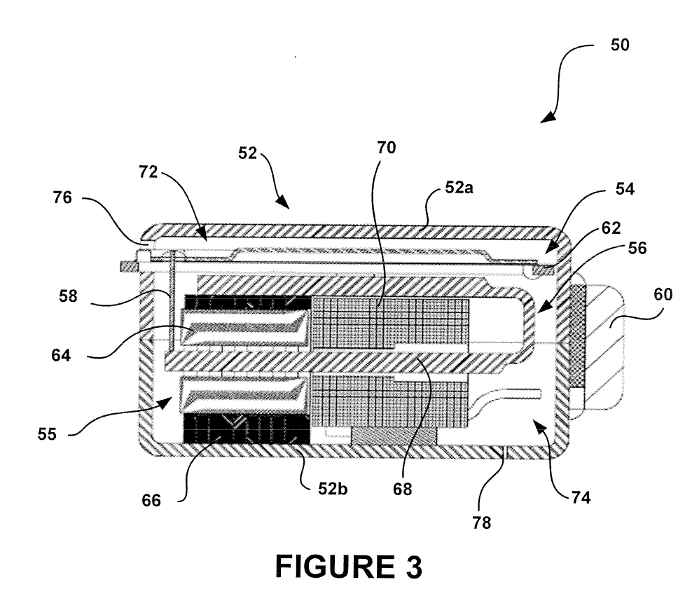

FIG. 3 illustrates a cross-sectional view of a transducer 50 that can be used in virtually any type of electroacoustic transducer system. The transducer 50 may be selected to have virtually any frequency response. For example, the transducer 50 maybe a tweeter, a MF receiver, a woofer, an upper-mid receiver, a lower-mid receiver, an upper-HF receiver, a lower-HF receiver, an upper-LF receiver, a lower-LF receiver or the like. The transducer 50 includes a housing 52 having a top housing 52a and a bottom housing 52b attached together by any known techniques, defining an inner cavity 55. An acoustic assembly 54, a motor assembly 56, and a coupling assembly 58 are disposed within the housing 52. While the housing 52 has a rectangular in cross-section shape, it will be understood that any housing shape or configuration suitable for virtually any desirable applications may suffice, including a roughly square shape, a rectangular shape, a cylindrical shape or any other desired geometry and size. The housing 52 may be manufactured from a variety of materials such as, for example, stainless steel, magnetic soft steel, non-conductive material, alternating layers of conductive and non-conductive materials, or the like. Use of other types of material that possess sufficient structural properties to form a housing is possible. An external terminal assembly 60 is fixedly attached to the rear portion of the housing 52 by any known techniques. The acoustic assembly 54 may be a single layer diaphragm, a multiple layer diaphragm, or the like and may be attached to a frame 62 and a flexible layer (not shown). The acoustic assembly 54 divides the inner cavity 55 into a front volume 72 and a back volume 74.

The coupling assembly 58 may be a drive rod, a linkage assembly, a plurality of linkage assemblies, or the like and may be made of an electrically conductive material. As shown in FIG. 3, one end of the coupling assembly is coupled to the acoustic assembly 54 and the other end of the coupling assembly 58 is coupled to the motor assembly 56 to drive the acoustic assembly 54. The motor assembly 56 may include a drive magnet 64, a magnetic yoke 66, an armature 68, and a drive coil 70. The coupling assembly 58 and the motor assembly 56 are disposed within the back volume 74. While the armature 68 is U-shaped, it will be understood that virtually any armature shape or configuration suitable for the desired application may suffice, including E shaped or any other desired geometry and size, without departing from the scope of the invention. A sound port 76 may be directly connected to the front volume 72 and formed on the housing 52 by any known techniques to allow acoustic energy to be transmitted to the user. An optional sound tube (not shown) connected to the sound port 76 may be coupled to the housing 52 by any known techniques to direct acoustic energy emitted from the sound port 76 to the user. An internal vent (not shown) directly connects between the front and back volumes 72, 74 and maybe is formed on the acoustic assembly 54 by any known techniques. Such an acoustic assembly 54 with a vent is commonly referred to as a pierced acoustic assembly. The internal vent facilitates a gas flow channel between the front and back volumes 72, 74 so as to maintain a static pressure difference of substantially zero between the deflectable acoustic assembly 54. Consequently, the internal vent may serve the purpose of pressure equalization in the inner cavity 55, or back volume 74, not connected directly with the external environment. An external vent 78 may also be provided that directly connects the back volume 74 to the external or surrounding environment. The external vent 78 may be formed on the bottom housing 52b by any known technique. It will be understood that more than one external vent connecting from the external or surrounding environment and the back volume 74 may be included without departing the scope of the invention. For example, the external vent 78 may comprise of a plurality of small holes. Preferably the plurality of small holes has an acoustic resistance with the acoustic resistance being chosen to be substantially equivalent to the single hole acoustic vent. More details about the internal vent and the external vent will follow. An optional damping member (not shown) may be provided to cover the external vent 78. The damping member may modify the acoustic characteristics and further prevent debris from clogging the vent 78. The damping member may be made of a material that is hydrophobic or a material made to be hydrophobic use of other types of material with acoustic proportion is possible.

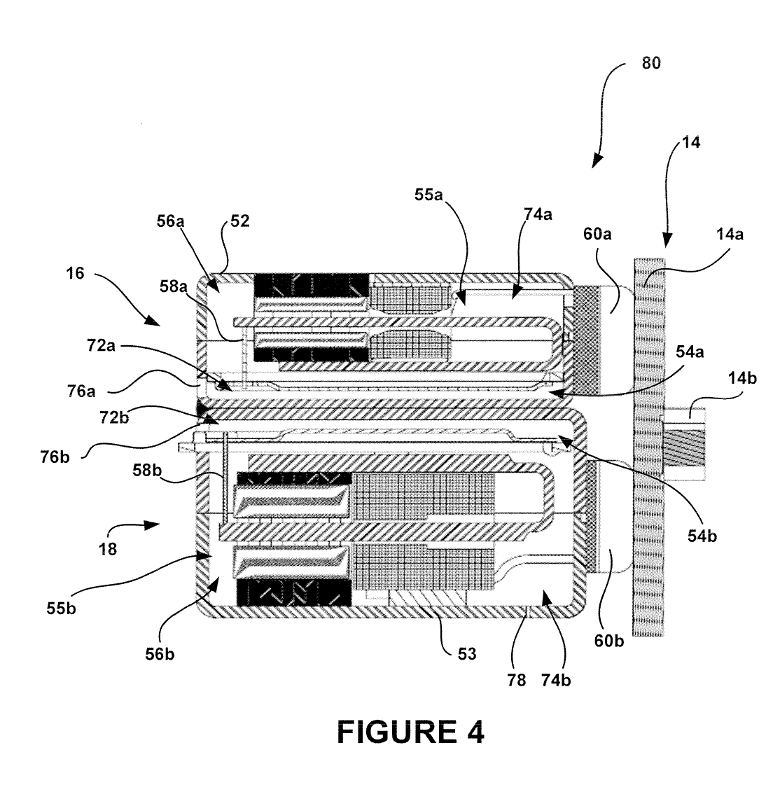

FIG. 4 illustrates a cross-sectional view of a dual transducer 80. The dual transducer 80 comprises a first transducer 16 and a second transducer 18. The transducers 16, 18 optionally may be mounted together in series or in parallel by any known techniques. A cross-over network 14 electrically couples to at least one of the external terminal assemblies 60a, 60b of the transducers 16, 18. Like transducer 50 in FIG. 3, the transducers 16, 18 may respectively include housings 52, 53, acoustic assemblies 54a, 54b, motor assemblies 56a, 56b, and coupling assemblies 58a, 58b. The acoustic assemblies 54a, 54b, motor assemblies 56a, 56b, and the coupling assemblies 58a, 58b are disposed in the inner cavities 55a, 55b of the housings 52, 53. The acoustic assemblies 54a, 54b divide the inner cavities 55a, 55b into front volumes 72a, 72b, and back volumes 74a, 74b. At least one internal vent (not shown) may be formed on the acoustic assemblies 54a, 54b. The internal vent may be formed by any known techniques. An acoustic assembly, such as assemblies 54a, 54b, with an internal vent is commonly referred to as a pierced acoustic assembly. The internal vent facilitates a gas flow channel between the front and back volumes 72a, 72b, 74a, 74b so as to maintain a static pressure difference of substantially zero between the deflectable acoustic assemblies 54a, 54b. Consequently, the internal vent may provide pressure equalization in the inner cavities 55a, 55b, or back volumes 74a, 75b, not connected directly with the external environment. At least one external vent 78 may be formed on the first transducer 16 or the second transducer 18 to connect one of the back volumes 74a, 74b to the external or surrounding environment. It will be understood that more than one external vent may be included without departing from the scope of the invention. For example, the external vent 78 may comprise of a plurality of small holes and such plurality of small holes may have an acoustic resistance equivalent to a single hole. An optional damping member (not shown) may be provided to cover the external vent 78. The damping member may modify the acoustic characteristics and further prevent debris from clogging the vent 78. The damping member may be made of a material that is hydrophobic or a material made to be hydophobic. Other types of material are possible.

Acoustic filter structures such as the internal vent, the external vent, damping members, or combination thereof used in the transducers 16, 18, 20 may optimize performance depending on the desired applications. For instance, a woofer with an external vent having a dimension greater than 0.003 inches, also known as a full vent, achieves an additional 3 dB bass at low frequencies while the peak resonance is lower than a woofer without the external vent. A woofer with an external vent having a dimension equal or smaller than 0.0003 inches also known as a resistive vent achieves a rising bass response from 1 kHz to 60 Hz while the first resonant frequency of the resistive vented woofer remains the same as the un-vented woofer. On the other hand, a tweeter with a resistive vent flattens the high frequency response while maintaining the resonant frequency as the un-vented tweeter. The woofer with an un-pierced acoustic assembly achieves a rising bass response from 1 KHz to frequency as low as 10 Hz while a woofer with a pierced acoustic assembly roll off at frequencies below 60 Hz.

An optional sound tube (not shown) may directly connect to the front volumes 72a, 72b and is formed on the housings 52, 53 by any known techniques to allow acoustic energy to be transmitted to the user via the sound ports 76a, 76b. It will be understood that more than one sound tube may be provided without departing from the scope of the invention. For instance, as shown the sound port 76a is communicating with a first sound tube and the sound port 76b is communicating with a second sound tube.

The cross-over network 14 may be a substrate 14a and include at least one discrete component 14b mounted to the substrate 14a. The substrate 14a may then electrically couple to one of the external terminal assemblies 60a, 60b of the transducers 16, 18. The substrate 14a may be a printed circuit board (PCB), a flexible circuit, a ceramic substrate, a thin film multichip module substrate, or similar substrate material. Furthermore, the substrate 14a may be a rigid or flexible support for one or more embedded electronic components. The use of other types of materials is possible. The substrate 14a is shown to have at least one layer. However, the substrate may utilize multiple layers, depending on the desired applications. In the embodiment shown, the substrate 14a is a PCB having a printed wiring trace (not shown) thereon. The component 14b may be a capacitor, inductor, a resistor or a combination thereof. Use of other component types is possible. The cross-over network 14 enables the system 80 to have an increase in the frequency output of the transducer above the cross-over frequency of from about 1 Kz to 6 KHz.

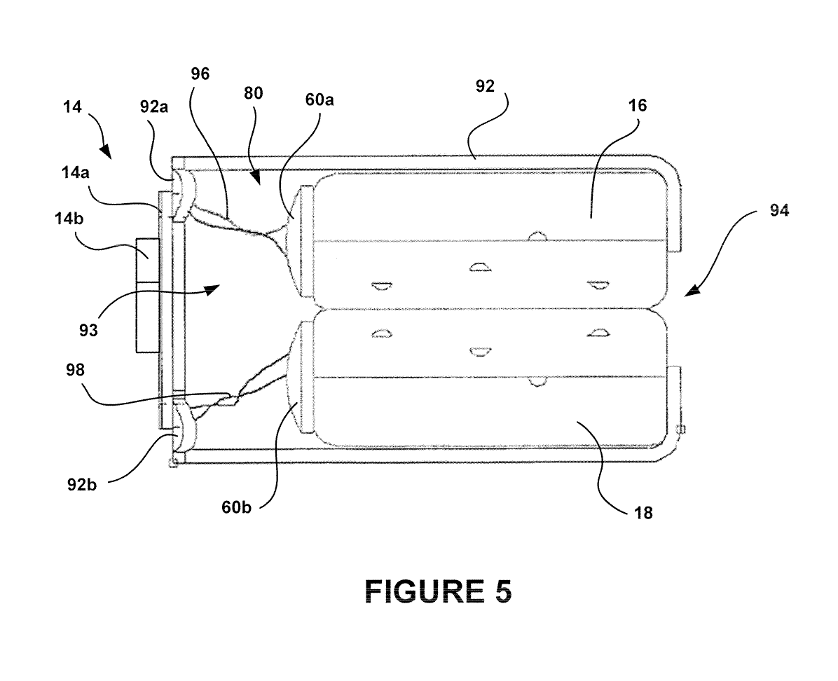

FIG. 5 illustrates a side elevational view of a dual transducer 80 disposed in an optional capsule 92. The capsule 92 may be generally rectangular in cross-section comprises an interior 93 for retaining at least one transducer 16 or 18 and an opening 94 for allowing acoustic energy to be transmitted to the user via the sound ports (not shown). It will be understood that the capsule 92 can be sized to accommodate more than two transducers without departing the scope of the invention. The capsule 92 may be made of highly magnetic-permeability material to attenuate unwanted electrical signals or noise produced by the transducers 16, 18. The capsule 92 may further form a shield against electromagnetic interference (EMI). If one of the transducers 16, 18 is operating as a low-frequency (LF) receiver and such LF receiver is housed in the capsule 92, the capsule 92 may be used as an additional venting volume for the LF receiver without risk of acoustic leakage. For example, the capsule 92 may be formed from a material selected from the group consisting of a Nickel-Iron-Molybdenum alloy, commonly available under the trade designation Carpenter HYMU 80 from Carpenter Technology Corporation, Hipernom from Carpenter Technology Corporation, a Moly Permalloy Alloy from Allegheny Ludlum Corporation, or of any similar materials. Other types of material are possible. The capsule 92 is shown to have at least one layer. However, the capsule 92 may utilize multiple layers, depending on the desired applications.

At least one through hole, e.g. 92a, 92b is formed on the rear portion of the capsule 92 by any conventional method to allow connecting internal wires 96, 98, or the like to pass through the holes 92a, 92b and couple to a signal source (not shown) via a cross-over network 14. The cross-over network 14 may be a substrate 14a may be fixedly attached to the rear portion of the capsule 92. The connecting internal wires 96, 98 electrically couple the terminals assemblies 60a, 60b of the transducers 16, 18 to the substrate 14a. The substrate 14a may have thereon a printed wiring trace (not shown) that may carry at least one discrete component 14b to pass a selected frequency and to attenuate the non-selected frequency from the source (not shown) from reaching one of the transducers 16, 18.

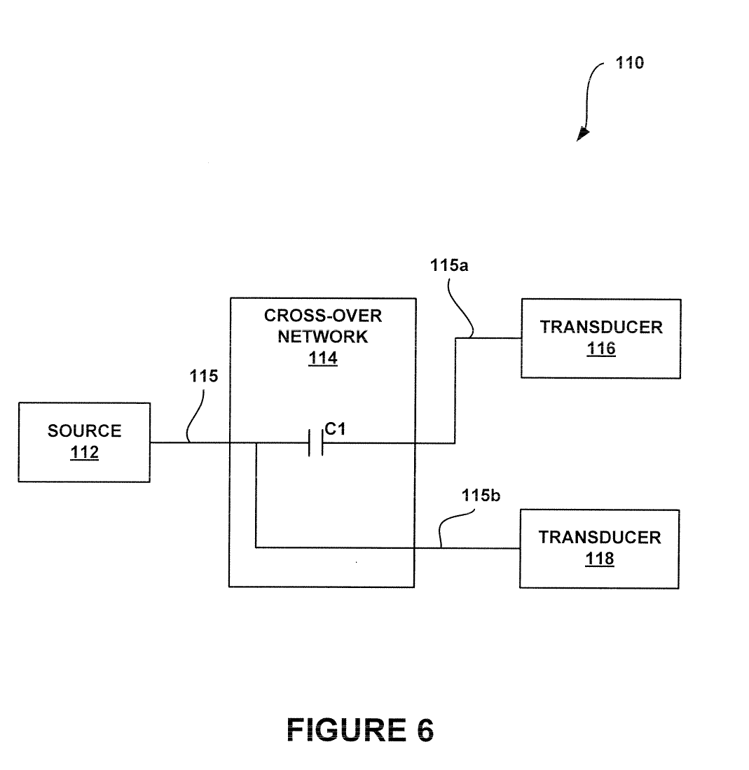

FIG. 6 illustrates a simplified block diagram of an electroacoustic transducer system 110. The system 110 comprises an audio signal source 112, a cross-over network 114, and a plurality of transducers 116, 118. The cross-over network 114 comprises at least one filter element, such as a capacitor C1 having a first end coupled to the signal source 112 via a line 115 and a second end coupled to an input of the transducer 116 via a line 115a. An input of the transducer 118 is coupled to the line 115 via a line 115b. The transducer 116 is a HF receiver which is also known as a tweeter and the transducer 118 is a LF receiver which is also known as a woofer. At least one acoustical filter, such as a full vent or a resistive vent may be formed on at least one of the transducers 116, 118 to improve the frequency output. For instance, the resistive vent for the tweeter 116 enables it to achieve a flatter HF response while the resistive vent for the woofer 118 enables to control the low frequency output and to maintain the first resonant frequency. The woofer 118 may be provided with an un-pierced acoustic assembly to reduce the LF roll-off.

It should be appreciated the cross-over network configuration, i.e., C1 in the cross-over network 114, is used to pass HF signals over line 115a to the tweeter 116 and may also be used to attenuate low frequency signals. In the embodiment, the cross-over network 114 is commonly referred to as a high-pass filter (HPF). Other types of filters may be employed, such as a resistor-capacitor filter, resistor-inductor filter, or the like, without departing from the scope of the invention. Typical values for C1 are in a range from approximately 0.01 uF to a range of 2.0 uF for the tweeter 116 may be selected to optimize the HF output.

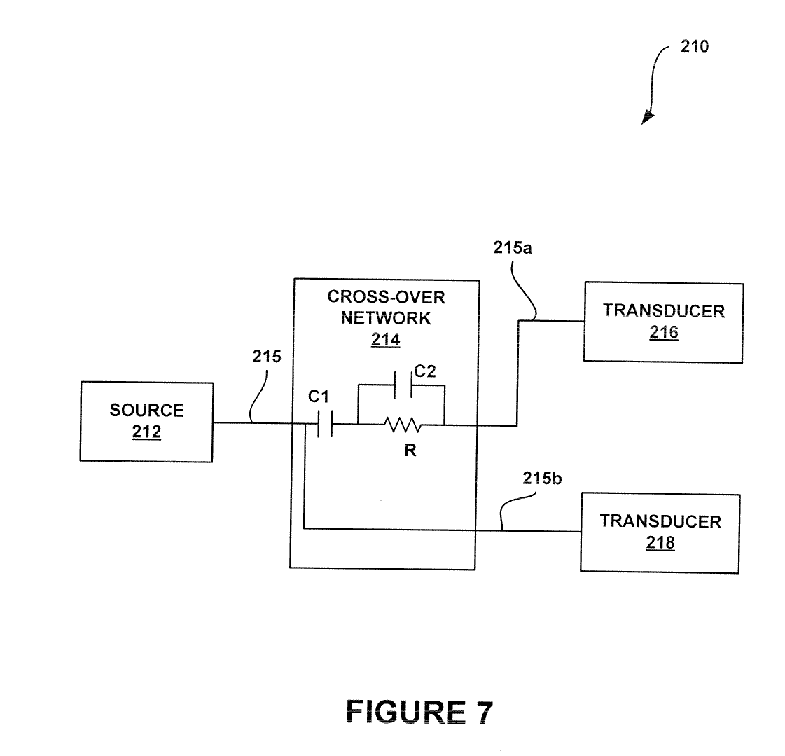

FIG. 7 illustrates a simplified block diagram of an electroacoustic transducer system 210. The system 210 comprises an audio signal source 212 and a plurality of transducers 216, 218. A cross-over network 214 for directing a HF input over line 215a to drive the tweeter 216 is provided. The cross-over network 214 comprises a first capacitor C1 and a resistor R connected in series with the transducer 216, e.g., a tweeter. A second capacitor C2 is connected in parallel with the resistor, R. At least one acoustical filter, such as a full vent or a resistive vent may be formed on at least one of the transducers 216, 218 to improve the frequency output. For instance, the resistive vent for the transducer 216, e.g., a tweeter, enables to achieve a flatter HF response while the resistive vent for the transducer 218, e.g., a woofer, provides control of the low frequency output and retains the first resonant frequency. The transducer 218 may be provided with an un-pierced acoustic assembly to reduce the LF roll-off.

It should be appreciated that the use of C1, C2, and R in the cross-over network 214 is to pass HF signals to the transducer 216 and may be also utilized to attenuate low frequency signals. Other types of filters may be employed, such as a resistor-capacitor filter, resistor-inductor filter, or the like. More than one filter may be included without departing from the scope of the invention.

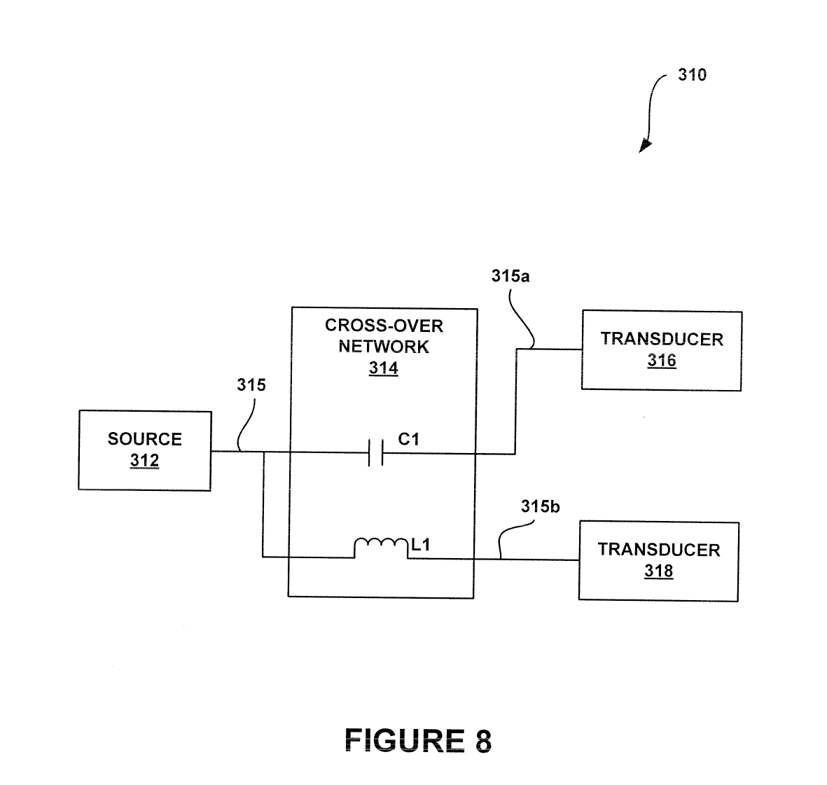

FIG. 8 illustrates a simplified block diagram of an electroacoustic transducer system 310. The system 310 comprises an audio signal source 312, at least one cross-over network, two are illustrated as 314, and a plurality of transducers 316, 318. The first cross-over network 314 comprises at least one filter element, such as a capacitor C1 that acts as a HPF. The HPF has a first end coupled to the signal source 312 via a line 315 and a second end coupled to an input of the transducer 316 via a line 315a. The second cross-over network 314 comprises an inductor L and acts as a LPF. The LPF has a first end coupled to the signal source 312 via the line 315 and a second end coupled to an input of the transducer 318 via a line 315b. In the embodiment, the transducer 316 is a HF receiver which is also known as a tweeter and the transducer 318 is a LF receiver which is also known as a woofer. At least one acoustical filter, such as a full vent or a resistive vent may be formed on at least one of the transducers 316, 318 or both the transducers 316, 318 to improve the frequency output. For instance, the resistive vent for the transducer 316 enables to achieve a flatter HF response while the resistive vent for the transducer 318 enables to control the low frequency output and to maintain the first resonant frequency. The transducer 318 may be provided with an un-pierced acoustic assembly to reduce the LF roll-off.

It should be appreciated in the art of the cross-over network configuration that the use of C1 in the cross-over network 314 is to pass HF signals over line 315a to the transducer 316 and may be also utilized to attenuate low frequency signals. Further, L passes LF signals over line 315b to the transducer 316 and attenuates high frequency signals. Other types of filter may be employed, such as a resistor-capacitor filter, resistor-inductor filter, or the like, without departing from the scope of the invention.

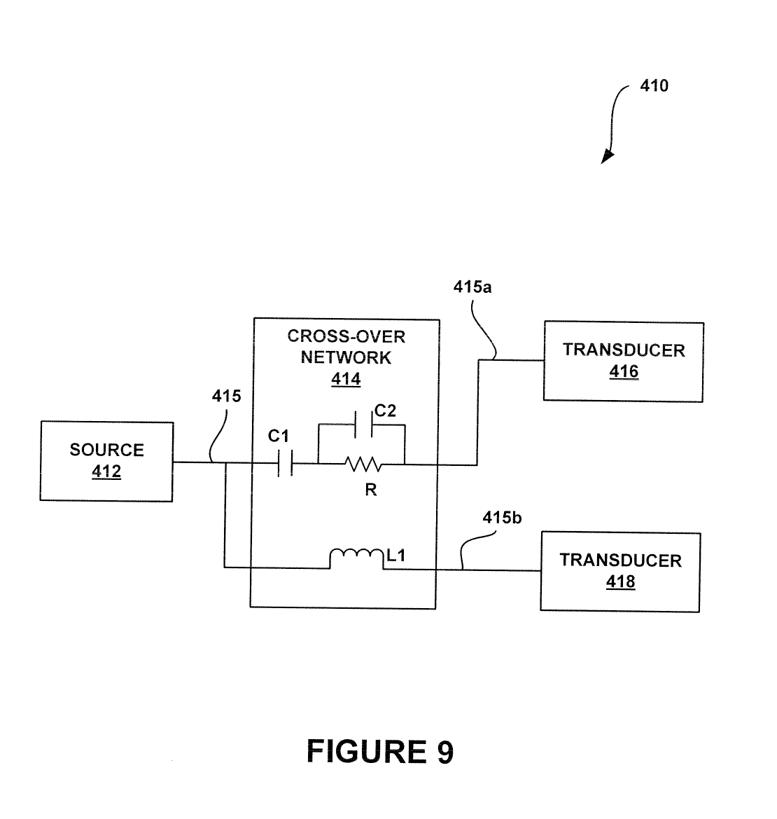

FIG. 9 illustrates a simplified block diagram of an electroacoustic transducer system 410. The system 410 comprises an audio signal source 412, at least one cross-over network, two are illustrated as 414, and a plurality of transducers 416, 418. A first cross-over network 414 may be provided for directing a HF input over line 415a to drive the transducer 416, e.g., a HF receiver. The first cross-over network 414 may include a first capacitor C1 and a resistor R connected in series with the transducer 416. A second capacitor C2 is connected in parallel with the resistor R. A second cross-over network 414 may include an inductor L. The second cross-over network 414 acts as a LPF, having a first end coupled to the signal source 412 via the line 415 and a second end coupled to an input of the transducer 418 via a line 415b. At least one acoustical filter, such as a full vent or a resistive vent may be formed on at least one of the transducers 416, 418 to improve the frequency output. For instance, the resistive vent for the transducer 416 enables it to achieve a flatter HF response while the resistive vent for the transducer 418 enables it to control the low frequency output and to retain the first resonant frequency. The transducer 418 may be provided with an un-pierced acoustic assembly to reduce the LF roll-off.

It should be appreciated that the use of C1, C2, and R in the cross-over network 414 is to pass HF signals to the transducer 416, i.e., HF receiver and may also attenuate low frequency signals. The use of L in the cross-over network 414 is to pass LF signals to the transducer 418, i.e., LF receiver and attenuates high frequency signals. Other types of filters may be employed, such as a resistor-capacitor filter, resistor-inductor filter, or the like. More than one filter may be included without departing from the scope of the invention.

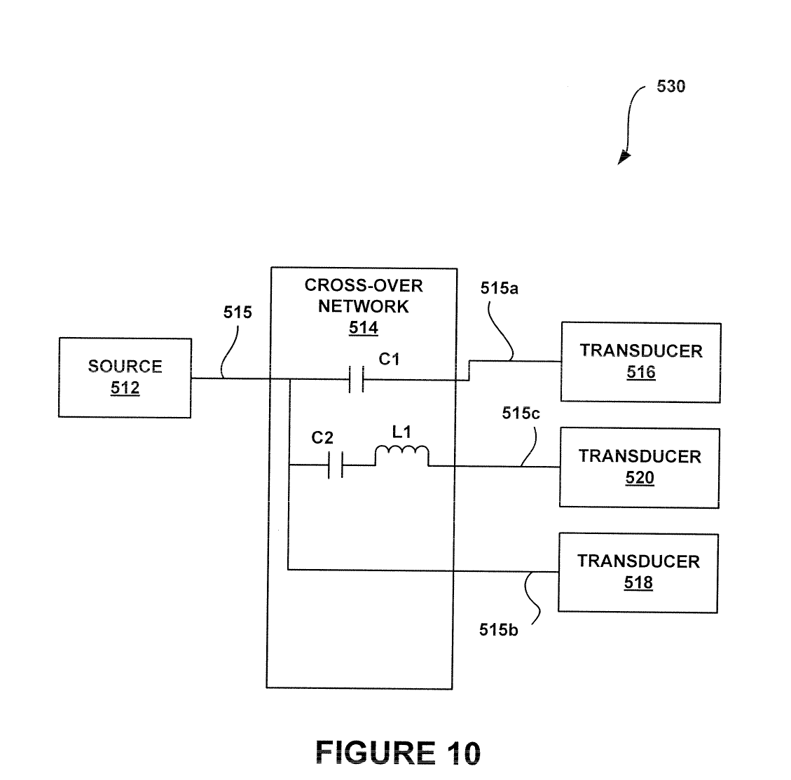

FIG. 10 illustrates a simplified block diagram of an electroacoustic transducer system 530. The system 510 may include an audio signal source 512, at least one cross-over network, two are illustrated as 514, and a plurality of transducers 516, 518, 520. In the embodiment the first transducer 516 is a tweeter, the second transducer 530 is a mid-range receiver, and the third transducer 518 is a woofer. It will be understood that the system 530 may include different combinations such as two tweeters and one woofer, two tweeters and one mid range receiver, two mid range receivers and one woofer, etc., depending on the desired application without departing from the scope of the invention. The first cross-over network 514 comprises at least one filter element, such as a capacitor C1 that acts as a HPF having a first end coupled to the signal source 512 via a line 515 and a second end coupled to an input of two tweeter 516. The second cross-over network 514 comprises a capacitor C2 and an inductor L1 coupled in series with the transducer 520, i.e., mid-range receiver, to direct a mid-range input frequency to drive the mid-range receiver 520 over a line 515c. As shown a first end of the C2 is coupled to the signal source 512. An input of the transducer 518, i.e., a woofer is coupled to the line 515 to direct the low input frequency via a line 115b to drive the transducer 518. At least one acoustical filter, such as a full vent or a resistive vent may be formed on at least one of the transducers 516, 518, 520 to improve the frequency output. For instance, the resistive vent for the transducer 516 enables to achieve a flatter HF response while the resistive vent for the transducer 518 enables to control the low frequency output and to maintain the first resonant frequency. The transducer 518 may be provided with an un-pierced acoustic assembly to reduce the LF roll-off.

It should be appreciated that the use of C1 in the cross-over network 514 is to pass HF signals over line 515a to the transducer 516 and may also attenuate low frequency signals. Further, C2 and L1 pass MF signals over line 515c to the transducer 516 and attenuates high frequency signals. Other types of filters may be employed, such as a resistor-capacitor filter, resistor-inductor filter, or the like, without departing from the scope of the invention.

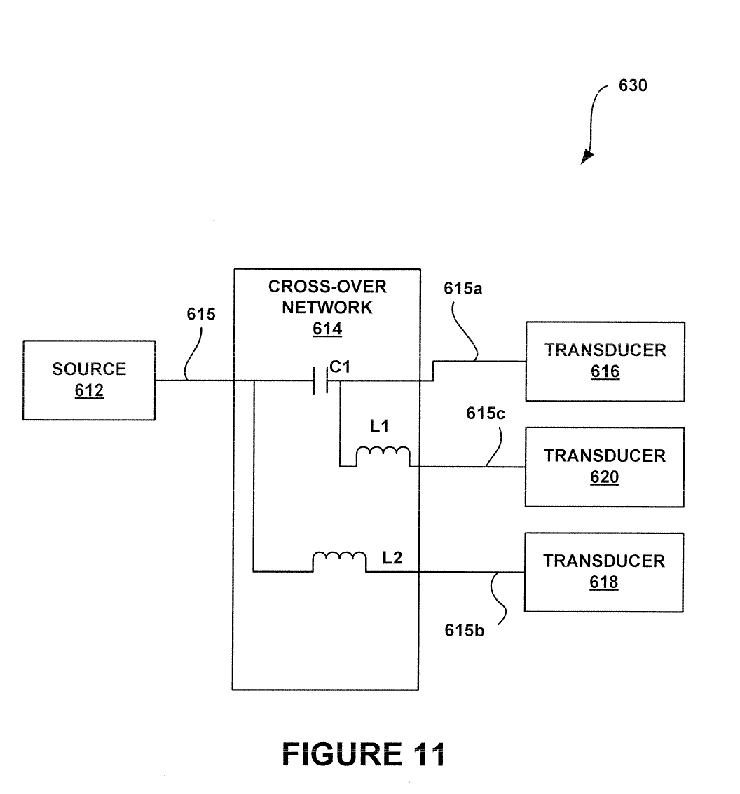

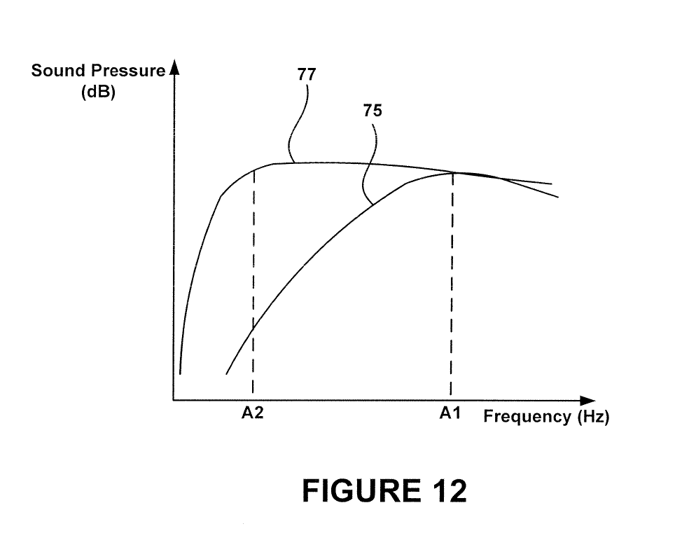

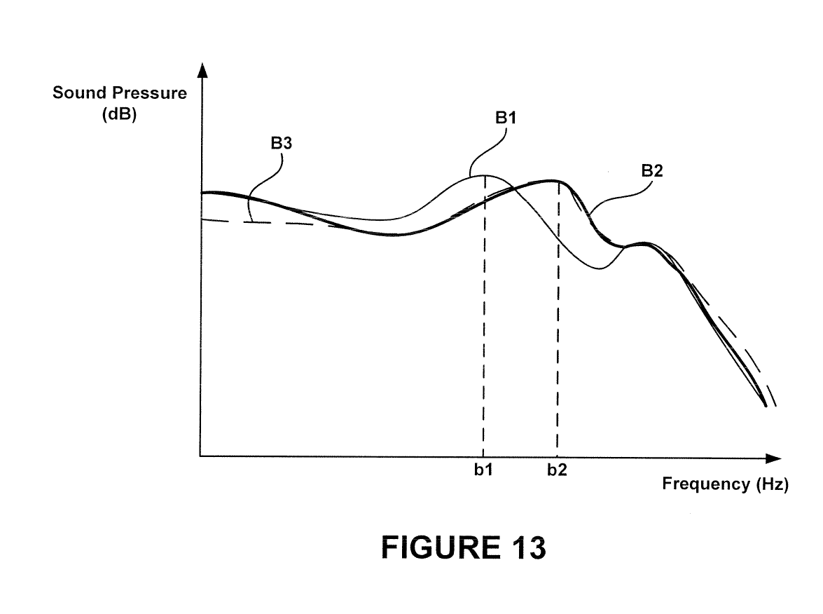

FIG. 11 illustrates a simplified block diagram of an electroacoustic transducer system 630. The system 610 may include an audio signal source 612, at least one cross-over network with three illustrated as 614, and a plurality of transducers 616, 618, 620. In the embodiment, the first transducer 616 is a tweeter, the second transducer 630 is a mid-range receiver, and the third transducer 618 is a woofer. It will be understood that the system 630 may include different transducer combinations such as two tweeters and one woofer, two tweeters and one mid range receiver, two mid range receivers and one woofer, depending on the desired applications without departing from the scope of the invention. The first cross-over network 614 comprises at least one filter element, such as a capacitor C1, that acts as a HPF, having a first end coupled to the signal source 612 via a line 615 and a second end coupled to an input of the transducer 616. The second cross-over network 614 may include an inductor L1 coupled in series with the mid-range receiver 620 to direct a mid-range input frequency to drive the transducer 620 over a line 615c. As shown a first end of L1 is coupled to the second end of C1 and a second end of L1 is coupled to the input of the mid-range receiver 620. The third cross-over network 614 comprises an inductor L2 having a first end coupled to the source 612 via the line 615 and a second end coupled to an input of the transducer 618 over line 615b to direct the low input frequency. At least one acoustical filter, such as a full vent or a resistive vent may be formed on at least one of the transducers 616, 618, 620 to improve the frequency output. For instance, the resistive vent for the transducer 616 enables to achieve a flatter HF response while the resistive vent for the transducer 618 enables to control the low frequency output and to maintain the first resonant frequency. The transducer 618 may be provided with an un-pierced acoustic assembly to reduce the LF roll-off.

It should be appreciated that the use of C1 in the cross-over network 614 is to pass HF signals over line 615a to the transducer 616 and may be also utilized to attenuate low frequency signals. Further, L1 passes MF signals over line 615c to the transducer 620 and attenuates high frequency signals and L2 passes F signals over line 615b to the transducer 618. Other types of filter may be employed, such as a resistor-capacitor filter, resistor-inductor filter, or the like, without departing from the scope of the invention.

FIG. 12 illustrates the results of two measurements obtained from two transducers having common frequency characteristics, for instance low-frequencies, in accordance with an embodiment of the present invention. The sound pressure is plotted as a function of the frequency. A first curve 75 represents a transducer with an internal vent and a second curve 77 represents a transducer without an internal vent. The graph indicates that the low frequency roll-off of the curve 75 is shifted towards an even lower frequency roll-off of the curve 77, for instance from A1 to A2 or lower, to enhance a stronger bass or low frequency response output. Mid or high frequencies transducers without internal vents do not have any influence on the low frequency response output.

FIG. 13 illustrates the results of three measurements obtained from three transducers, in accordance with an embodiment of the present invention. The sound pressure is plotted as a function of the frequency. In order to obtain a shift in frequency and change the shape of the curve, three transducers having common frequency characteristics are used. A first curve B1 represents a response of a transducer with an external vent having a dimension greater than 0.003 inches. A second curve B2 represents a response of a transducer with an external vent having a dimension of equal or less than 0.003 inches. A third curve B3 represents a response of a transducer without an external vent. The graph clearly indicates that as the dimension of the external vent decreases, the result is a change in the shape of the curves. An increased frequency b2 of the curve B2 from b1 is resulted, while maintaining the first resonant frequency as B3.

Returning back to FIGS. 3 and 4, the motor assembly may be modified or adjusted to further improve the selected frequency output performance. For instance, the armature may be made shorter having a length of from about 0.01 to 0.200 inches. The affect is to increase the mechanical stiffness of the armature driven by the drive coil and the magnetic yoke. The drive coil has a correspondingly different length to accommodate the armature. In one embodiment, the drive coil may have a length of from about 0.01 to 0.200 inches. In order to drive the armature having an increased stiffness, the drive magnets may require a greater force. This can be achieved by selection and dimensions of the magnetic material, e.g., using an increased thickness of material. In one embodiment, the drive magnets may have a thickness of from about 0.005 to 0.03 inches to provide sufficient electromagnetic flux density to drive the armature.

All references, including publications, patent applications, and patents, cited herein are hereby incorporated by reference to the same extend as if each reference were individually and specifically indicated to be incorporated by reference and were set forth in its entirety herein.

Preferred embodiments of this invention are described herein including the best mode known to the inventors for carrying out the invention. It should be understood that the illustrated embodiments are exemplary only, and should not be taken as limiting the scope of the invention.

What is claimed is:

1. An electroacoustic transducer system including a nigh frequency transducer and a low frequency transducer, each of the transducers comprising:
a housing, the housing defining an inner cavity, an acoustic assembly disposed within the housing for creating sound pressure divides the inner cavity into a front volume and a back volume, and
a cross-over network coupled to the high frequency transducer for directing a high input frequency to drive the high frequency transducer;
wherein each of the transducers comprises an acoustical filter formed on a wall of the housing communicating between the back volume and a surrounding environment.

2. The electroacoustic transducer system of claim 1, wherein the cross-over network is selected from the group comprising a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

3. The electroacoustic transducer system of claim 1, comprising a second cross-over network coupled to the low frequency transducer, the second cross-over being a low frequency cross-over.

4. The electroacoustic transducer system of claim 3, wherein the second cross-over network is selected from the group comprising a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

5. The electroacoustic transducer system of claim 1, wherein the acoustical filter is an external vent.

6. The eletroacoustic transducer system of claim 5, wherein the acoustical filter has an opening dimension equal or less than 0.003 inches.

7. The electroacoustic transducer system of claim 5, wherein the acoustical filter has an opening dimension greater than 0.003 inches.

8. The electroacoustic transducer system of claim 1, wherein the acoustic assembly of the low frequency transducer is un-pierced.

9. The electroacoustic transducer system of claim 1, the high frequency transducer comprising a shorter armature, a shorter drive coil, and thicker drive magnets.

10. The electroacoustic transducer system of claim 1, wherein a mid range frequency transducer is coupled in parallel with the high frequency transducer and the low frequency transducer.

11. The electroacoustic transducer system of claim 10, wherein a third cross-over network couples to the mid frequency transducer, the third cross-over being a mid frequency cross-over.

12. The electroacoustic transducer system of claim 11, wherein the third cross-over network is selected from the group consisting of a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

13. The electroacoustic transducer system of claim 1, wherein a capsule is provided to encapsulate the system, the capsule including a shield against electromagnetic interference.

14. The electroacoustic transducer system of claim 13, wherein the capsule is made of a highly magnetic-permeability material and the housing attentuates of electrical signals or noise produced by the transducers.

15. An electroacoustic transducer system comprising a high frequency transducer, a mid frequency transducer, and a low frequency transducer coupled in parallel, the system comprising:
an audio signal source; and
a first cross-over network coupled between the audio signal source and one of the transducers, the first cross-over having a first selected input frequency response;
wherein each transducer comprises an acoustical filter providing an extended high frequency output and a sustained low frequency output.

16. The electroacoustic transducer system of claim 15, wherein the first cross-over network is coupled to the high frequency transducer, the first cross-over being a high frequency cross-over.

17. The electroacoustic transducer system of claim 15, wherein a second cross-over network is coupled with the audio signal source and the mid frequency transducer, the second cross-over network being a mid frequency cross-over.

18. The electroacoustic transducer system of claim 15, wherein a second cross-over network is coupled with the first cross-over network and the mid frequency transducer, the second cross-over network being a mid frequency cross-over.

19. The electroacoustic transducer system of claim 15, wherein a third cross-over network is coupled with the audio signal source and the low frequency transducer, the third cross-over being a low frequency cross-over.

20. The electroacoustic transducer system of claim 12, wherein each of the transducers comprises:
a housing, the housing defining an inner cavity, an acoustic assembly disposed within the housing dividing the inner cavity into a front volume and a back volume; and
an acoustical filter formed on a wall of each housing for communicating the back volume with the surrounding environment.

21. The electroacoustic transducer system of claim 15, wherein the first cross-over network is selected from the group comprising of a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

22. The electroacoustic transducer system of claim 15, wherein the acoustical filter is an external vent.

23. The electroacoustic transducer system of claim 22, wherein the acoustical filter has an opening dimension equal or less than 0.003 inches.

24. The electroacoustic transducer system of claim 22, wherein the acoustical filter has an opening dimension greater than 0.003 inches.

25. The electroacoustic transducer system of claim 15, wherein the acoustic assembly of the low frequency transducer is un-pierced.

26. The electroacoustic transducer system of claim 15, wherein the high frequency transducer comprising a shorter armature, a shorter drive coil, and thicker drive magnets.

27. The electroacoustic transducer system of claim 15, wherein a capsule is provided to encapsulate the system, the capsule comprising a shield against electromagnetic interference.

28. The electroacoustic transducer system of claim 28, wherein the capsule is made of highly magnetic-permeability material and attenuates unwanted electrical signals or noise produced by the transducers.

29. The electroacoustic transducer system comprising:
a first transducer;
a second transducer; and
a cross-over network coupled to the first transducer or the second transducer for directing selected signals to drive the first transducer or the second transducer, respectively;
wherein the first transducer or the second transducer comprises a resistive vent.

30. The electroacoustic transducer system of claim 29, wherein each of the transducers comprise:
a housing defining an inner cavity;
an acoustic assembly disposed within the housing dividing the inner cavity into a front volume and a back volume; and
the resistive vent being formed on a wall of the housing for communicating the back volume and the surrounding.

31. The electroacoustic transducer system of claim 30, wherein the first transducer and the second transducer are coupled to an audio signal source.

32. The electroacoustic transducer system of claim 30, wherein the first and second transducers are selected from a group comprising of a high-frequency (HF) receiver, mid-range frequency receiver, low frequency (LF) receiver, upper HF receiver, lower HF receiver, upper mid-range frequency receiver, lower mid-range frequency receiver, upper LF receiver, lower LF receiver, or combination thereof.

33. The electroacoustic transducer system of claim 30, wherein the first transducer is a woofer, the woofer comprising the resistive vent to boost the low frequency output while maintaining the first resonance frequency.

34. The electroacoustic transducer system of claim 30, wherein the first transducer is a tweeter and the second transducer is a woofer, each transducer comprising a resistive vent to provide an extended high frequency output and a sustaintial low frequency output.

35. The electroacoustic transducer system of claim 30, wherein the first transducer or the second transducer comprises an un-pierced acoustic assembly.

36. The electroacoustic transducer system of claim 31, wherein a third transducer is coupled to the audio signal source.

37. The electroacoustic transducer system of claim 36, wherein a second cross-over network is coupled to the third transducer.

38. A method of making an electroacoustic transducer system comprising:
providing a first transducer including a back volume and a front volume defined by an acoustic assembly formed within a housing;
providing a second frequency transducer including a back volume and a front volume defined by an acoustic assembly formed within the housing;
coupling a cross-over network to one of the first transducer or the second transducer, the cross-over network directing a selected input frequency to drive said one transducer;
forming an acoustical filter on a wall of the housing of said one transducer;
and communicating the back volume and the surrounding via the acoustical filter.

39. The method of claim 38, wherein the cross-over network is selected from the group consisting of a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

40. The method of claim 38, comprises coupling a second cross-over network to the second transducer, the second cross-over network directing the remaining input frequency to drive the second transducer.

41. The method of claim 40, wherein second cross-over network is selected from the group consisting of a passive filter, an active filter, a biamplification circuit, a triamplification circuit, an audio cross-over, a N-way cross-over, an analog cross-over, a digital cross-over, a discrete-time (sampled) cross-over, a continuous-time cross-over, a linear filter, a non-linear filter, an infinite impulse response filter, a finite impulse response filter or combinations thereof.

42. The method of claim 38, wherein the acoustical filter is an external vent,

43. The method of claim 38, wherein the acoustical filter has an opening dimension equal or less than 0.003 inches.

44. The method of claim 38, wherein the acoustical filter has an opening dimension greater than 0.003 inches.

45. The method of claim 38, wherein the acoustic assembly of the said one transducer is un-pierced.

46. The method of claim 38, wherein the said one transducer has a shorter armature, a shorter drive coil, and a thicker drive magnets.

47. The method of claim 38, comprising coupling a third transducer to the first and second transducers.

48. The method of claim 47, comprising coupling a third cross-over network to the third transducer.

49. The method of claim 38, comprising providing a capsule to the first and second transducer.

50. The method of claim 49, wherein the capsule is made of highly magnetic-permeability material and attenuates unwanted electrical signals or noise produced by the transducers.
